(19) United States
(12) Patent Application Publication
(10) Pub. No.: US 2025/0372485 A1
(43) Pub. Date: Dec. 4, 2025

(54) SEMICONDUCTOR DEVICE

(71) Applicant: Rohm Co., Ltd., Kyoto-shi (JP)

(72) Inventor: Naoyuki SANO, Kyoto-shi (JP)

(21) Appl. No.: 19/299,869

(22) Filed: Aug. 14, 2025

Related U.S. Application Data
(63) Continuation of application No. PCT/JP2024/004038, filed on Feb. 7, 2024.

(30) Foreign Application Priority Data
Feb. 21, 2023 (JP) 2023-024856

(51) Int. Cl. H01L 23/495; H01L 23/31

(52) U.S. Cl. CPC H01L 23/49541; H01L 23/3121; H01L 23/49582

(57) ABSTRACT

A semiconductor device includes a first wiring layer, a semiconductor element conductively bonded to the first wiring layer, a second wiring layer positioned on a same side in a first direction as the first wiring layer with respect to the semiconductor element, a pillar connected and conductively bonded to the second wiring layer, and a metal layer positioned on a side opposite to the first wiring layer and the second wiring layer with respect to the semiconductor element, and connected to and electrically conductive with the pillar. The second wiring layer is spaced apart from the first wiring layer. The semiconductor element has an upper surface facing the metal layer. The metal layer is in contact with the upper surface.

### TECHNICAL FIELD

The present disclosure relates to a semiconductor device.

### BACKGROUND ART

WO 2016/203804 discloses an example of a semiconductor device comprising a wiring layer, a semiconductor element conductively bonded to the wiring layer by flip-chip bonding, and a passive element conductively bonded to the wiring layer. The passive element is an inductor. The passive element is laminated on the semiconductor device. This configuration enables miniaturization of the device.

On the other hand, further diversification of functions in semiconductor devices has been sought. As part of this diversification, a metal layer is sometimes laminated on the wiring layer with a semiconductor device sandwiched between them. In the semiconductor device disclosed in WO 2016/203804, the metal layer can be used as a conductive path for the passive element. However, in a case where a metal layer is laminated on the wiring layer with the semiconductor device in between, this results in an increase in the dimensions of the semiconductor device in the direction in which the metal layer is laminated.

### BRIEF DESCRIPTION OF THE DRAWINGS

FIG. 1 is a plan view of a semiconductor device according to a first embodiment of the present disclosure.

FIG. 2 is a plan view corresponding to FIG. 1, showing an electronic element and a second sealing resin in transparency.

FIG. 3 is a plan view corresponding to FIG. 2, omitting the illustration of the electronic element and a first sealing resin, and showing the two semiconductor elements and the second sealing resin in transparency.

FIG. 4 is a bottom view of the semiconductor device shown in FIG. 1.

FIG. 5 is a cross-sectional view along line V-V in FIG. 2.

FIG. 6 is a cross-sectional view along line VI-VI in FIG. 2.

FIG. 7 is a cross-sectional view along line VII-VII in FIG. 2.

FIG. 8 is a partial enlarged view of FIG. 5.

FIG. 9 is a partial enlarged view of FIG. 7, showing one of the two semiconductor elements and its vicinity.

FIG. 10 is a partial enlarged view of FIG. 6.

FIG. 11 is a partial enlarged view of FIG. 7, showing one of a plurality of terminals and its vicinity.

FIG. 12 is a cross-sectional view illustrating the manufacturing process of the semiconductor device shown in FIG. 1.

FIG. 13 is a cross-sectional view illustrating the manufacturing process of the semiconductor device shown in FIG. 1.

FIG. 14 is a cross-sectional view illustrating the manufacturing process of the semiconductor device shown in FIG. 1.

FIG. 15 is a cross-sectional view illustrating the manufacturing process of the semiconductor device shown in FIG. 1.

FIG. 16 is a cross-sectional view illustrating the manufacturing process of the semiconductor device shown in FIG. 1.

FIG. 17 is a cross-sectional view illustrating the manufacturing process of the semiconductor device shown in FIG. 1.

FIG. 18 is a cross-sectional view illustrating the manufacturing process of the semiconductor device shown in FIG. 1.

FIG. 19 is a cross-sectional view illustrating the manufacturing process of the semiconductor device shown in FIG. 1.

FIG. 20 is a cross-sectional view illustrating the manufacturing process of the semiconductor device shown in FIG. 1.

FIG. 21 is a cross-sectional view illustrating the manufacturing process of the semiconductor device shown in FIG. 1.

FIG. 22 is a cross-sectional view illustrating the manufacturing process of the semiconductor device shown in FIG. 1.

FIG. 23 is a cross-sectional view illustrating the manufacturing process of the semiconductor device shown in FIG. 1.

FIG. 24 is a cross-sectional view illustrating the manufacturing process of the semiconductor device shown in FIG. 1.

FIG. 25 is a cross-sectional view illustrating the manufacturing process of the semiconductor device shown in FIG. 1.

FIG. 26 is a cross-sectional view illustrating the manufacturing process of the semiconductor device shown in FIG. 1.

FIG. 27 is a cross-sectional view illustrating the manufacturing process of the semiconductor device shown in FIG. 1.

FIG. 28 is a plan view of a semiconductor device according to a second embodiment of the present disclosure, showing the electronic element and the second sealing resin in transparency.

FIG. 29 is a cross-sectional view along line XXIX-XXIX in FIG. 28.

FIG. 30 is a cross-sectional view along line XXX-XXX in FIG. 28.

### DETAILED DESCRIPTION OF EMBODIMENTS

The embodiments for implementing the present disclosure will be described with reference to the accompanying drawings.

### First Embodiment

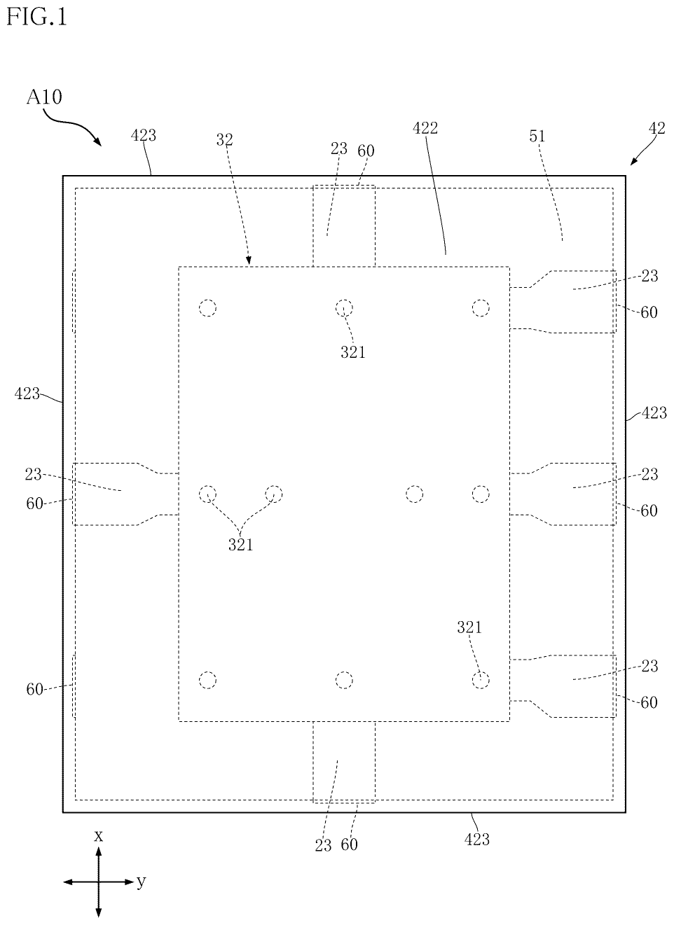

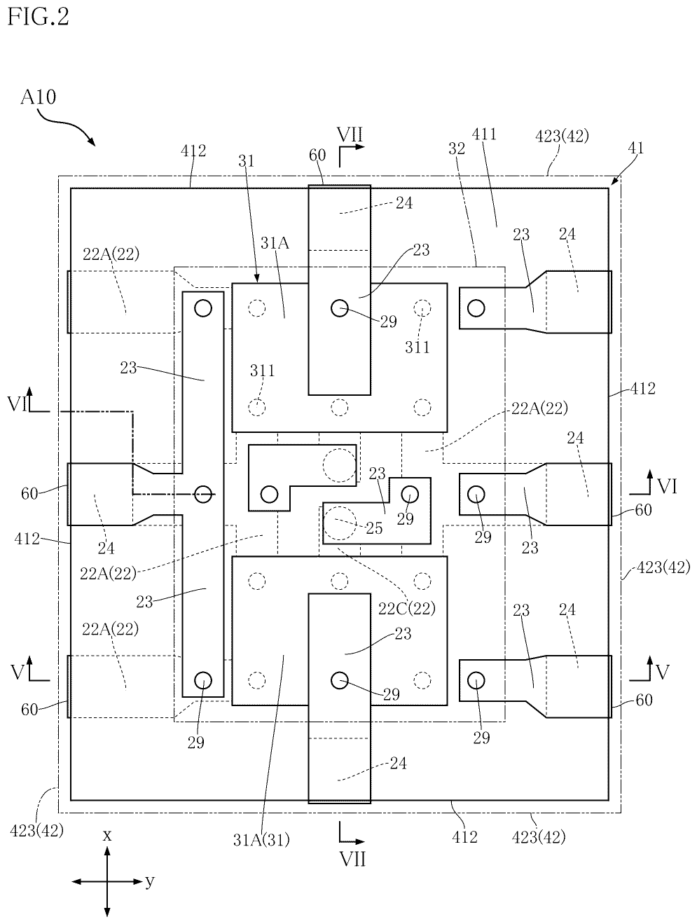

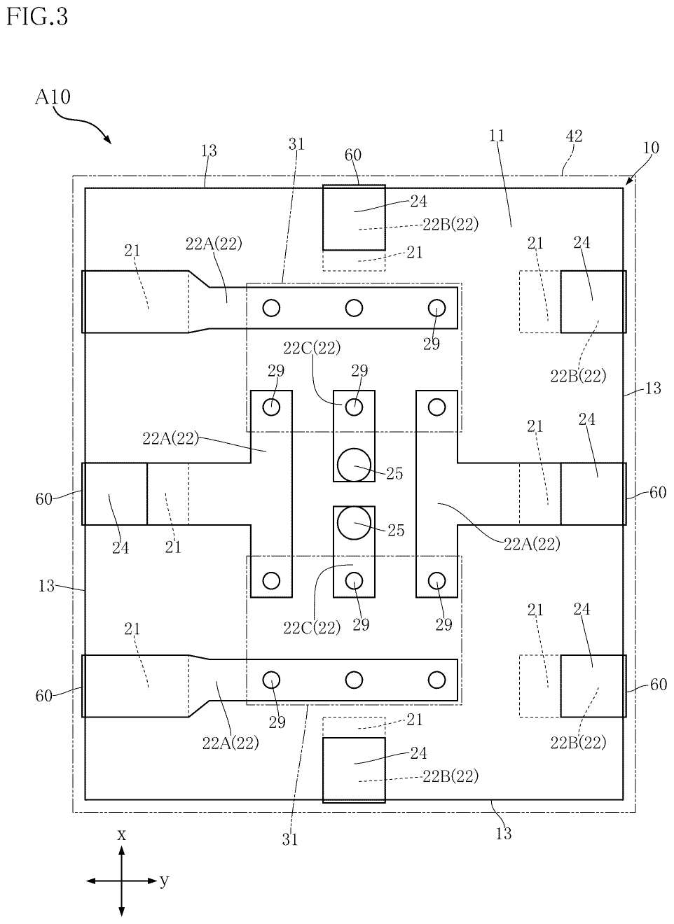

Based on FIGS. 1 to 7, a semiconductor device A10 according to a first embodiment of the present disclosure is described. The semiconductor device A10 includes an insulating layer 10, a plurality of terminals 21, a plurality of wiring layers 22, a plurality of metal layers 23, a plurality of pillars 24, a plurality of internal pillars 25, a conductive bonding layer 29, two semiconductor elements 31, an electronic element 32, a first sealing resin 41, a second sealing resin 42, and a plurality of protective layers 60. The semiconductor device A10 is in a resin package form that is surface-mounted on a wiring substrate. This resin package form is a QFN (quad flat non-leaded package). Here, FIG. 2 is shown for ease of understanding, with the electronic element 32 and the second sealing resin 42 being transparent. In FIG. 2, the electronic component 32 and the second sealing resin 42 that are transparent are indicated by imaginary lines (two-dot dashed lines). FIG. 3 omits the illustration of the electronic component 32 and the first sealing resin 41 for ease of understanding, and shows the two semiconductor elements 31 and the second sealing resin 42 in transparency. In FIG. 3, the two transparent semiconductor elements 31 and the second sealing resin 42 are each indicated by imaginary lines.

In the description of semiconductor device A10, for convenience, the normal direction of the mounting surface 11 of the insulating layer 10 to be described later is referred to, for example, as the “first direction z.” An example of a direction orthogonal to the first direction z is referred to as the “second direction x.” A direction orthogonal to the first direction z and the second direction x is referred to as the “third direction y.” As shown in FIG. 1, the semiconductor device A10 is rectangular as viewed in the first direction z.

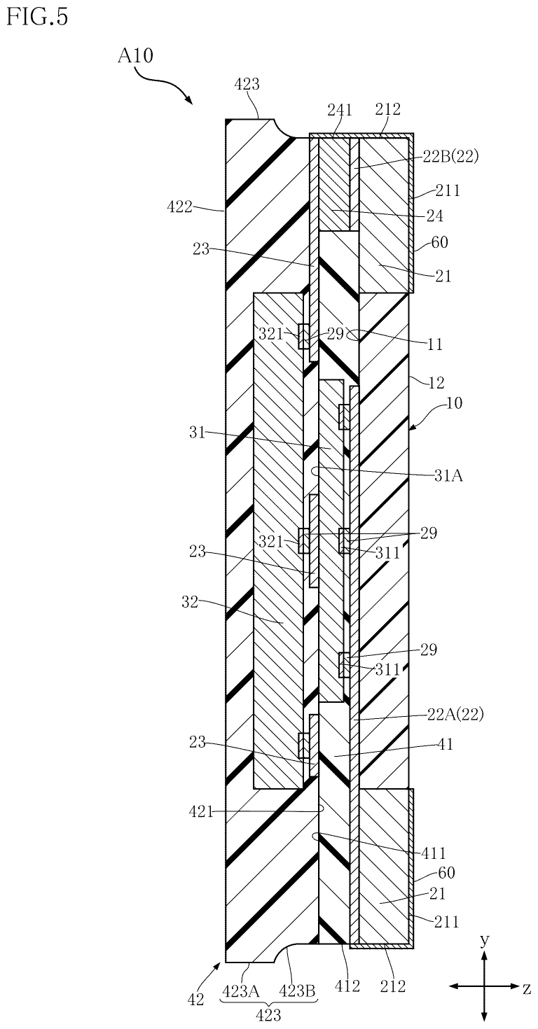

The insulating layer 10 is, as shown in FIGS. 5 to 7, mounted with the plurality of wiring layers 22 and the first sealing resin 41. The insulating layer 10 has electrical insulating properties. An example of the material of the insulating layer 10 is black epoxy resin. The insulating layer 10 has a mounting surface 11, a bottom surface 12, and a plurality of first side surfaces 13. The mounting surface 11 and the bottom surface 12 face each other in the first direction z. The mounting surface 11 faces the same side as the first surface 411 of the first sealing resin 41 to be described later in the first direction z. The mounting surface 11 faces the plurality of wiring layers 22 and the first sealing resin 41. The bottom surface 12 is exposed to the outside. When the semiconductor device A10 is mounted on the wiring board, the bottom surface 12 faces the wiring board. Each of the plurality of first side surfaces 13 faces a direction orthogonal to the first direction z. Each of the plurality of first side surfaces 13 is connected to the mounting surface 11 and the bottom surface 12. The plurality of first side surfaces 13 include two first side surfaces 13 facing the second direction x and two first side surfaces 13 facing the third direction y.

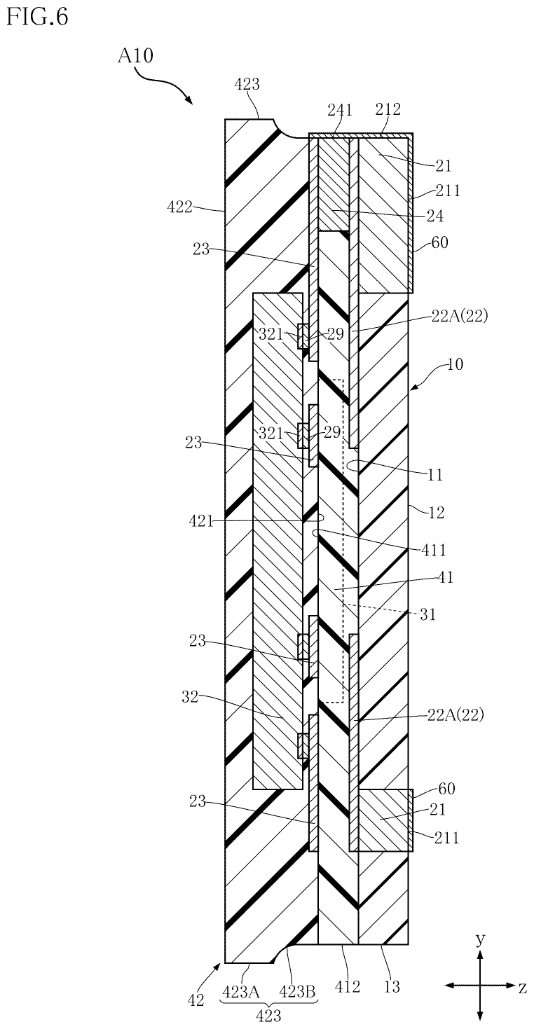

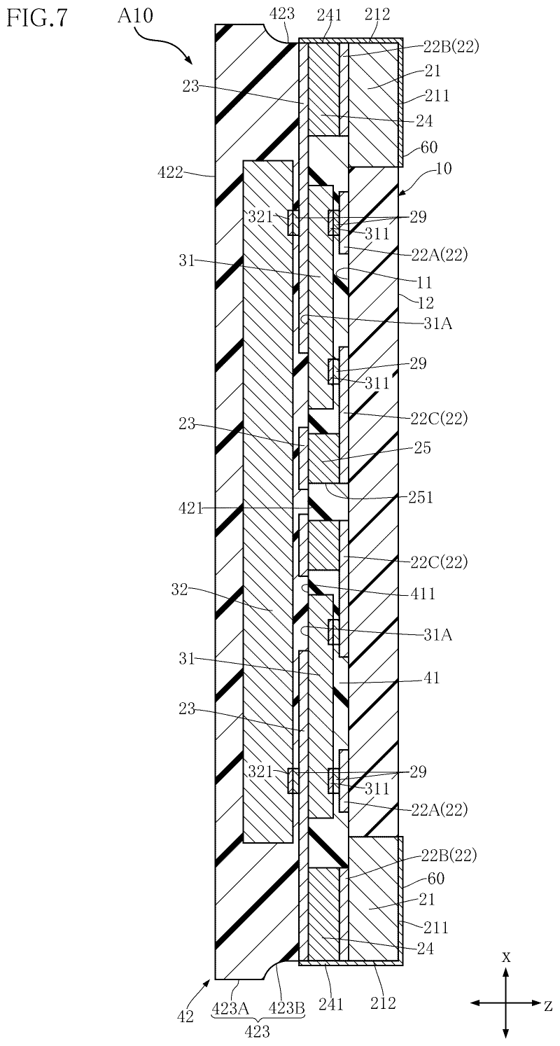

The first sealing resin 41 covers the two semiconductor elements 31 as shown in FIGS. 5 and 7. The first sealing resin 41 has electrical insulating properties. An example of the material of the first sealing resin 41 is black epoxy resin. The first sealing resin 41 is in contact with the mounting surface 11 of the insulating layer 10. As shown in FIGS. 2, 5, and 6, the first scaling resin 41 has a first surface 411 and a plurality of second side surfaces 412.

As shown in FIGS. 5 and 7, the first surface 411 faces the same side as an upper surface 31A of each of the two semiconductor elements 31 to be described later in the first direction z. Each of the plurality of second side surfaces 412 faces a direction orthogonal to the first direction z. Each of the plurality of second side surfaces 412 is connected to the first surface 411. The plurality of second side surfaces 412 include two second side surfaces 412 facing the second direction x and two second side surfaces 412 facing the third direction y.

Each of the plurality of terminals 21 is accommodated in the insulating layer 10, as shown in FIGS. 5 to 7. The plurality of terminals 21, together with the plurality of wiring layers 22, the plurality of metal layers 23, the plurality of pillars 24, and the plurality of internal pillars 25, form a conductive path between the two semiconductor elements 31 and the electronic element 32, and the wiring substrate on which the semiconductor device A10 is mounted. Each of the plurality of terminals 21 is connected to and is electrically conductive with either of a plurality of first wiring layers 22A or a plurality of second wiring layers 22B to be described later from among the plurality of wiring layers 22. The plurality of terminals 21 contain copper (Cu).

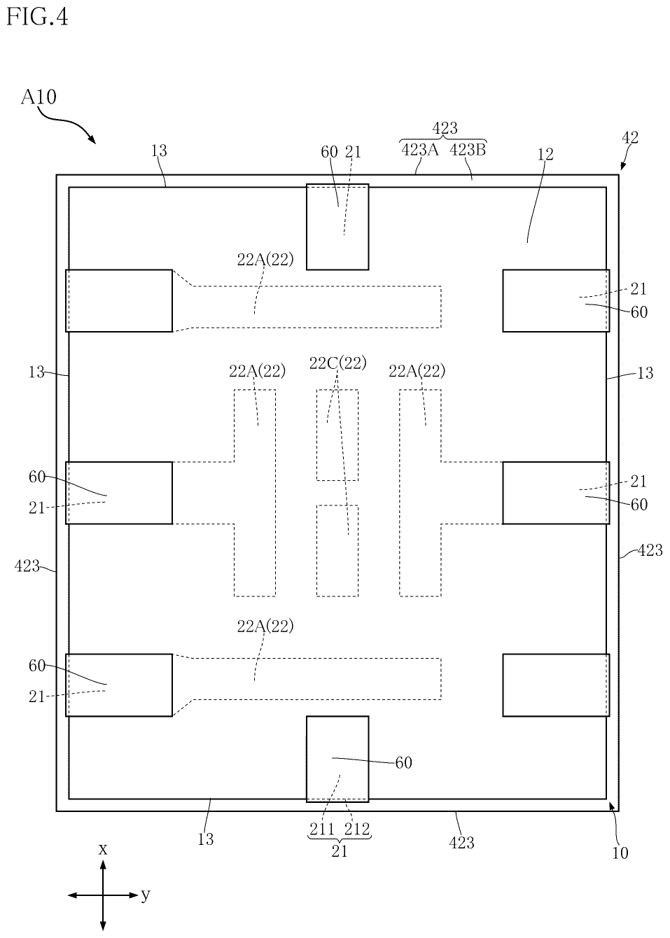

As shown in FIGS. 4 to 7, each of the plurality of terminals 21 has an implementing surface 211 and a side surface 212. The implementing surface 211 faces the same side as the bottom surface 12 of the insulating layer 10 in the first direction z. The implementing surface 211 is exposed from the bottom surface 12. The side surface 212 faces a direction orthogonal to the first direction z. The side surface 212 is exposed from one of the plurality of first side surfaces 13 of the insulating layer 10.

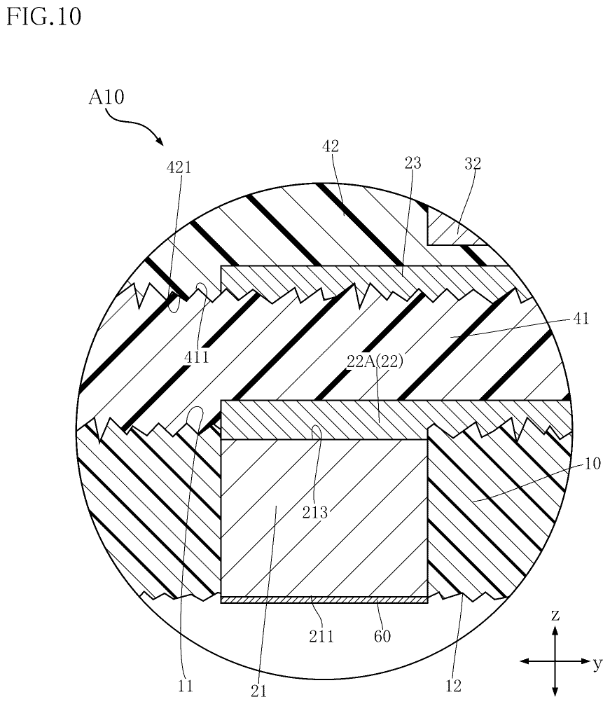

As shown in FIG. 10, each of the plurality of terminals 21 has a connection surface 213. The connection surface 213 faces the same side as the mounting surface 11 of the insulating layer 10 in the first direction z. The connection surface 213 is in contact with one of the plurality of first wiring layers 22A and the plurality of second wiring layers 22B to be described later from among the plurality of wiring layers 22. In the first direction z, the connection surface 213 is positioned between the bottom surface 12 and the mounting surface 11 of the insulating layer 10.

The plurality of wiring layers 22 are arranged on the mounting surface 11 of the insulating layer 10, as shown in FIGS. 5 to 7. Each of the plurality of wiring layers 22 is in contact with the mounting surface 11. The plurality of wiring layers 22 contain copper.

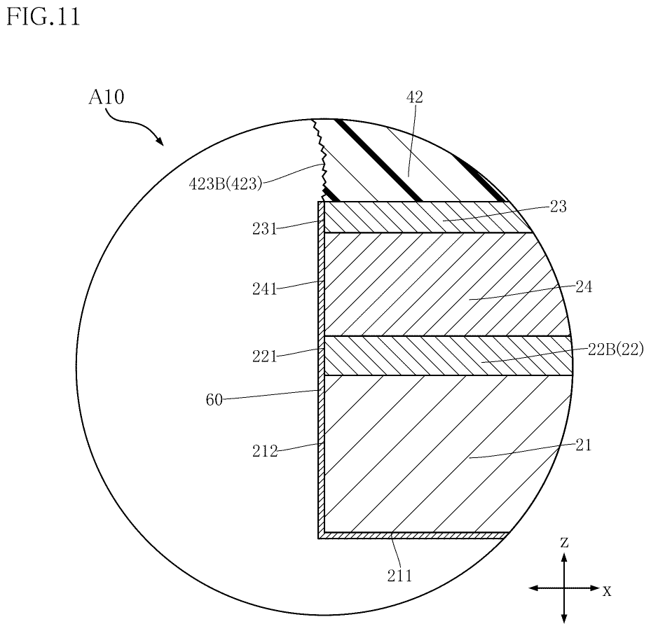

As shown in FIGS. 5 to 7, the plurality of wiring layers 22 are accommodated within the first sealing resin 41. As shown in FIG. 11, at least one of the plurality of wiring layers 22 has a first end surface 221 facing a direction orthogonal to the first direction z. The first end surface 221 is exposed from the first sealing resin 41.

As shown in FIG. 3, the plurality of wiring layers 22 include the plurality of first wiring layers 22A, the plurality of second wiring layers 22B, and a plurality of third wiring layers 22C. Each of the plurality of second wiring layers 22B is spaced apart from the plurality of first wiring layers 22A and the plurality of third wiring layers 22C. As a result, each of the plurality of second wiring layers 22B is not electrically connected to the plurality of first wiring layers 22A.

Each of the two semiconductor elements 31 is electrically bonded to the plurality of first wiring layers 22A and the plurality of third wiring layers 22C, as shown in FIGS. 5 and 7. The two semiconductor elements 31 are spaced apart from each other in the second direction x. The two semiconductor elements 31 are, for example, LSIs (Large Scale Integrations).

As shown in FIGS. 5 and 7, each of the two semiconductor elements 31 has a plurality of electrodes 311. Each of the plurality of electrodes 311 faces one of the plurality of wiring layers 22. Each of the plurality of electrodes 311 is conductively bonded to either of the plurality of first wiring layers 22A or the plurality of third wiring layers 22C via the conductive bonding layer 29. The conductive bonding layer 29 contains nickel (Ni), tin (Sn), and silver (Ag). Additionally, the conductive bonding layer 29 may also contain nickel, tin, and antimony (Sb).

As shown in FIGS. 2, 5, and 7, each of the two semiconductor elements 31 has an upper surface 31A facing one of the plurality of metal layers 23 in the first direction z. The upper surface 31A faces the same side as the first surface 411 of the first scaling resin 41 in the first direction z. The upper surface 31A is exposed from the first surface 411.

The plurality of metal layers 23 are positioned on the opposite side of the plurality of first wiring layers 22A, the plurality of second wiring layers 22B, and the plurality of third wiring layers 22C, with respect to the two semiconductor elements 31, as shown in FIGS. 5 to 7. The plurality of metal layers 23 contain copper.

As shown in FIGS. 5 to 7, the plurality of metal layers 23 are accommodated in the second scaling resin 42. Each of the plurality of metal layers 23 is in contact with the first surface 411 of the first sealing resin 41. As shown in FIG. 11, at least one of the plurality of metal layers 23 has a second end surface 231 facing a direction orthogonal to the first direction z. The second end surface 231 is exposed from the second sealing resin 42.

As shown in FIG. 2, as viewed in the first direction z, at least one of the plurality of metal layers 23 overlaps the upper surface 31A of at least one of the two semiconductor elements 31. As viewed in the first direction z, the metal layer 23 overlapping the upper surface 31A is in contact with the upper surface 31A and is electrically conductive with the upper surface 31A.

The electronic element 32 is electrically bonded to the plurality of metal layers 23 as shown in FIGS. 5 to 7. As shown in FIG. 2, as viewed in the first direction z, the electronic element 32 overlaps each of the two semiconductor elements 31. The electronic element 32 is, for example, an LSI. Additionally, the electronic element 32 may be various other semiconductor elements. Furthermore, the electronic element 32 may be a passive element such as an inductor. As shown in FIGS. 5 to 7, the electronic element 32 has a plurality of electrodes 321. Each of the plurality of electrodes 321 faces one of the plurality of metal layers 23. Each of the plurality of electrodes 321 is electrically bonded to one of the plurality of metal layers 23 via the conductive bonding layer 29. The electronic element 32 is electrically conductive with the upper surface 31A of each of the two semiconductor elements 31.

Each of the plurality of pillars 24 is positioned between one of the first wiring layers 22A and the second wiring layers 22B in the first direction z, and one of the plurality of metal layers 23, as shown in FIGS. 5 to 7. Each of the plurality of pillars 24 is connected to and is electrically conductive with either of the plurality of first wiring layers 22A and the plurality of second wiring layers 22B. Furthermore, each of the plurality of pillars 24 is connected to and is electrically conductive with one of the plurality of metal layers 23. As a result, each of the plurality of pillars 24 is electrically conductive with one of the plurality of first wiring layers 22A and the plurality of second wiring layers 22B, and with one of the plurality of metal layers 23. The plurality of pillars 24 contain copper.

As shown in FIGS. 5 to 7, the plurality of pillars 24 are accommodated in the first scaling resin 41. Each of the plurality of pillars 24 has a first circumferential surface 241 facing a direction orthogonal to the first direction z. The first circumferential surface 241 is exposed from the first sealing resin 41.

The plurality of internal pillars 25 are positioned, as shown in FIG. 2, more inwardly in the second sealing resin 42 than the plurality of second side surfaces 412 of the first sealing resin 41 are, as viewed in the first direction z. Each of the plurality of internal pillars 25 is positioned between one of the plurality of third wiring layers 22C and one of the plurality of metal layers 23 as viewed in the first direction z. Each of the plurality of internal pillars 25 is connected to and is electrically conductive with one of the plurality of third wiring layers 22C. Furthermore, each of the plurality of internal pillars 25 is connected to and is electrically conductive with one of the plurality of metal layers 23. As a result, each of the plurality of internal pillars 25 is electrically conductive with one of the plurality of third wiring layers 22C and one of the plurality of metal layers 23. Each of the plurality of internal pillars 25 is not electrically conductive with the plurality of terminals 21. As shown in FIG. 7, each of the plurality of internal pillars 25 has a second circumferential surface 251 facing a direction orthogonal to the first direction z. The second circumferential surface 251 is covered by the first sealing resin 41. The plurality of internal pillars 25 contain copper.

The second sealing resin 42 covers the electronic component 32, as shown in FIGS. 5 to 7. The second sealing resin 42 has electrical insulating properties. An example of the material of the second sealing resin 42 is black epoxy resin. As shown in FIGS. 5 to 7, the second sealing resin 42 has a second surface 421, a top surface 422, and a plurality of third side surfaces 423.

As shown in FIGS. 5 to 7, the second surface 421 faces a side to be opposed to the first surface 411 of the first sealing resin 41 in the first direction z and is in contact with the first surface 411. The top surface 422 faces a side opposite to the side the second surface 421 faces in the first direction z. Each of the plurality of third side surfaces 423 is connected to the second surface 421 and the top surface 422. Each of the plurality of third side surfaces 423 includes a first region 423A and a second region 423B. The first region 423A is connected to the top surface 422. The second region 423B is connected to the second surface 421 and the first region 423A. As viewed in the first direction z, the second region 423B overlaps the top surface 422. As shown in FIG. 2, as viewed in the first direction z, each of the plurality of third side surfaces 423 includes a portion located more outwardly than each of the plurality of second side surfaces 412 of the first sealing resin 41 is.

As shown in FIG. 8, the surface roughness of each of the first surface 411 of the first sealing resin 41 and the second surface 421 of the second sealing resin 42 is greater than the surface roughness of the top surface 422 of the second sealing resin 42. The surface roughness of each of the plurality of second side surfaces 412 of the first sealing resin 41 is smaller than the surface roughness of the first surface 411 and is larger than the surface roughness of the top surface 422. As shown in FIGS. 8 and 10, the surface roughness of each of the mounting surface 11 and bottom surface 12 of the insulating layer 10 is larger than the surface roughness of the top surface 422.

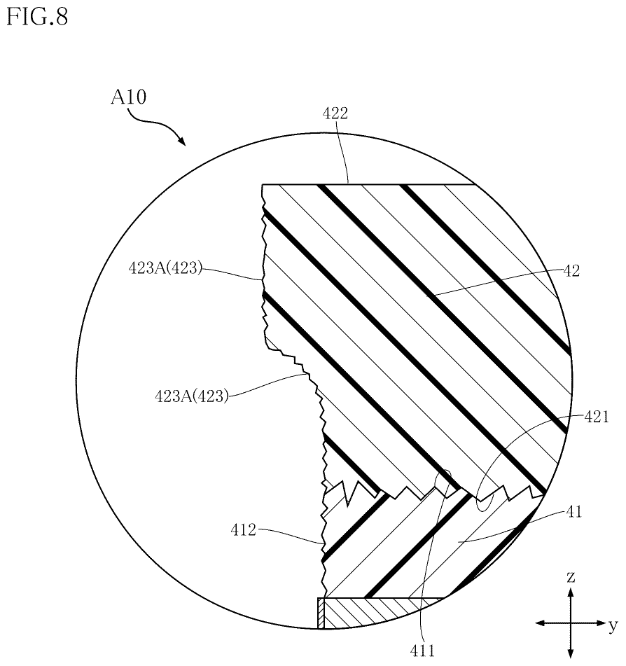

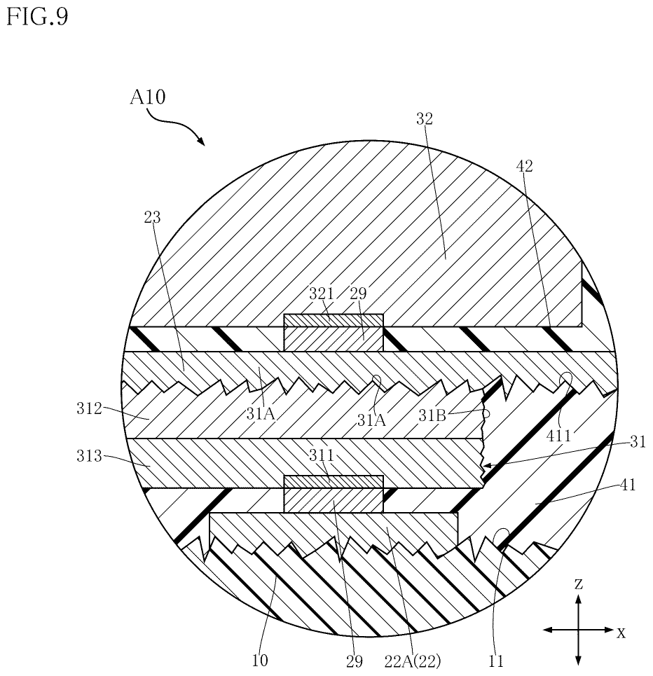

As shown in FIG. 9, each of the two semiconductor elements 31 has an end surface 31B, a semiconductor substrate 312, and a semiconductor layer 313. The end surface 31B faces a direction orthogonal to the first direction z. The end surface 31B is covered by the first scaling resin 41. In each of the two semiconductor elements 31, the surface roughness of the upper surface 31A is greater than the surface roughness of the end surface 31B. The semiconductor substrate 312 includes the upper surface 31A. The semiconductor layer 313 is laminated on the semiconductor substrate 312. The semiconductor substrate 312 includes the end surface 31B. In the semiconductor substrate 312, a plurality of circuits and a rewiring layer that conducts electricity to the plurality of circuits are formed. The plurality of electrodes 311 are electrically conductive with the rewiring layer formed on the semiconductor substrate 312. The semiconductor substrate 312 is electrically conductive with the semiconductor layer 313. Therefore, at least one of the plurality of metal layers 23 electrically conductive with the upper surface 31A is electrically conductive with the semiconductor layer 313.

The plurality of protective layers 60 are exposed to the outside, as shown in FIGS. 2 to 4. As shown in FIGS. 4 to 7, each of the plurality of protective layers 60 individually covers the implementing surface 211 and side surface 212 of each of the plurality of terminals 21. As shown in FIG. 11, one of the plurality of protective layers 60 covers the first end surface 221 of one of the plurality of wiring layers 22, the second end surface 231 of one of the plurality of metal layers 23, and the first circumferential surface 241 of one of the plurality of pillars 24.

The plurality of protective layers 60 are conductive. By conductively bonding the plurality of protective layers 60 to the wiring substrate via solder, the semiconductor device A10 is mounted on the wiring substrate. Each of the plurality of protective layers 60 includes a plurality of conductor layers. The plurality of conductor layers are laminated in the order of a nickel layer and a gold (Au) layer, starting from the side closer to any of the plurality of terminals 21. Alternatively, the plurality of conductor layers may be laminated in the order of a nickel layer, a palladium (Pd) layer, and a gold layer, starting from the side closer to any of the plurality of terminals 21. Therefore, each of the plurality of protective layers 60 contains gold.

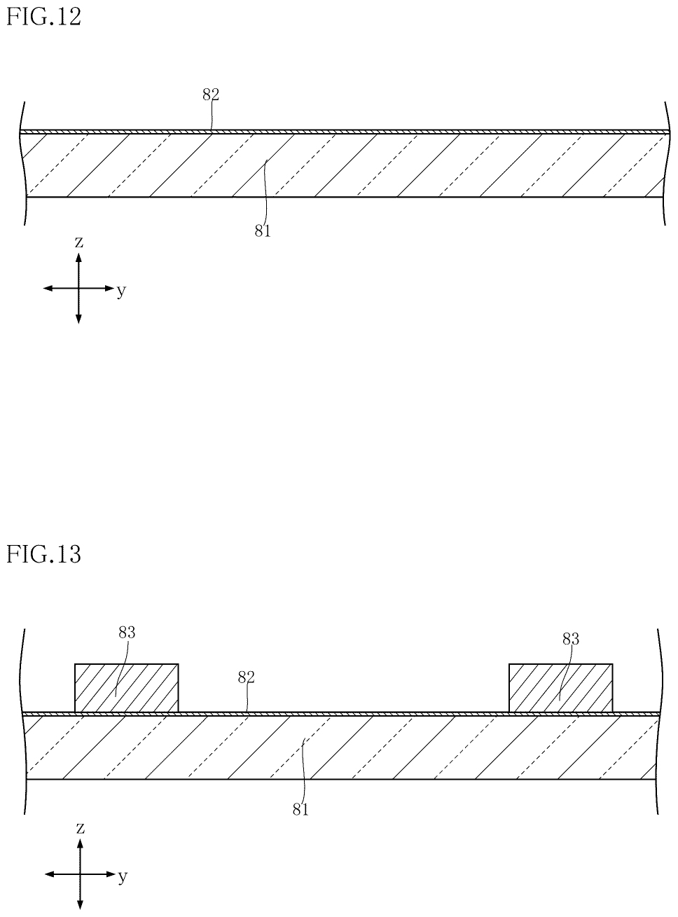

Next, based on FIGS. 12 to 27, an example of a manufacturing method for the semiconductor device A10 will be described. Here, the cross-sectional positions in FIGS. 12 to 27 are the same (or approximately the same) as those in FIG. 5.

First, as shown in FIG. 12, an intermediate layer 82 is formed to cover one side in the first direction z of the support member 81. The support member 81 is, for example, a silicon wafer. The intermediate layer 82 is constituted by a metal thin film made of titanium in contact with the support member 81 and a metal thin film made of copper laminated on said metal thin film. The intermediate layer 82 is formed by sputtering to deposit these metal thin films, respectively.

Next, as shown in FIG. 13, a plurality of conductive layers 83 are formed protruding in the first direction z from the intermediate layer 82. A portion of each of the plurality of conductive layers 83 becomes one of the plurality of terminals 21 which the semiconductor device A10 has. In forming the plurality of conductive layers 83, first, lithography patterning is performed on the intermediate layer 82. Next, a plurality of conductive layers 83 are deposited by electroplating using the intermediate layer 82 as a conductive path. Finally, the mask layer used for the lithography patterning is removed. Thus, the formation of a plurality of conductive layers 83 is completed.

Next, as shown in FIG. 14, a first resin layer 84 is formed to cover the plurality of conductive layers 83. A portion of the first resin layer 84 becomes the insulating layer 10 which the semiconductor device A10 has. The first resin layer 84 is made of a material containing black epoxy resin. The first resin layer 84 is formed by transfer mold forming. In this case, the first resin layer 84 is formed so as to contact the intermediate layer 82 and cover the whole of the plurality of conductive layers 83.

Next, as shown in FIG. 15, a portion of each of the plurality of conductive layers 83 and a portion of the first resin layer 84 are removed by grinding. The portions to be removed are those located on a side opposite to the side facing the intermediate layer 82 in the first direction z. As a result, each of the plurality of conductive layers 83 is exposed from the surface of the first resin layer 84 facing the first direction z.

Next, as shown in FIG. 16, a peripheral groove 811 is formed on the support member 81 such that it surrounds the first resin layer 84 as viewed in the first direction z and is recessed in the first direction z.

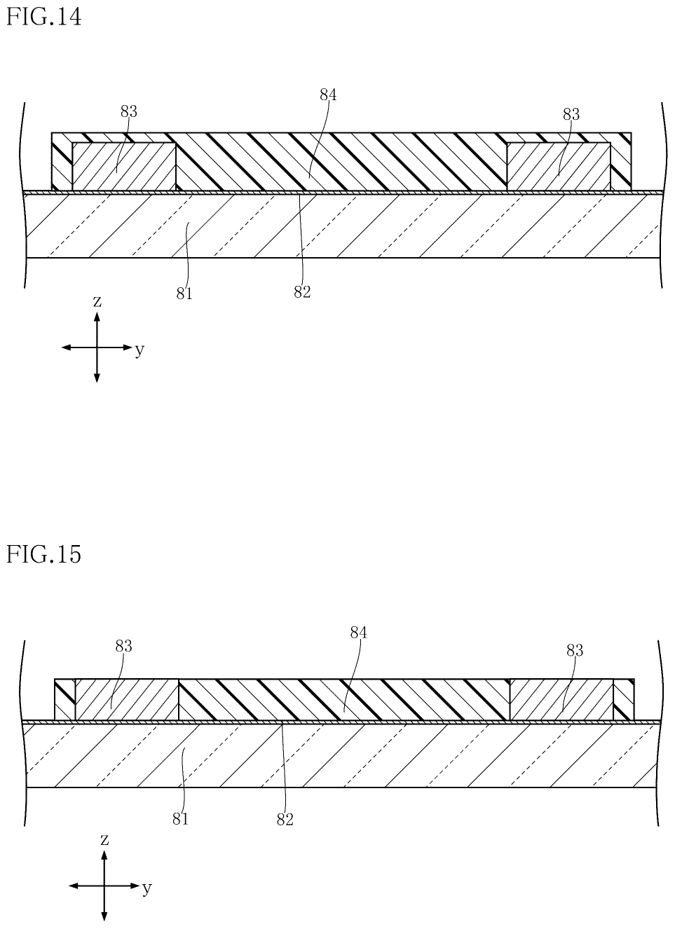

Next, as shown in FIG. 17, the plurality of conductive layers 83 and the plurality of wiring layers 22 in contact with the first resin layer 84 are formed. Additionally, conductive bonding layers 29, the plurality of pillars 24, and the plurality of internal pillars 25 laminated on one of the plurality of wiring layers 22 are formed. In forming the plurality of wiring layers 22, first, a surface of each of the plurality of conductive layers 83 exposed externally from the first resin layer 84 is smoothed by wet etching. Next, a seed layer (not shown) covering the plurality of conductive layers 83 and the first resin layer 84 is formed. The seed layer is composed of the same metal thin film as the intermediate layer 82. The seed layer is formed by sputtering. Next, lithography patterning is applied to the seed layer. Then, a plurality of wiring layers 22 are deposited by electroplating using the seed layer as a conductive path. Finally, the mask layer used for the lithography patterning is removed. Thus, the formation of the plurality of wiring layers 22 is completed.

To form the conductive bonding layer 29, the plurality of pillars 24, and the plurality of internal pillars 25, lithography patterning is applied to the aforementioned seed layer and the plurality of wiring layers 22. Next, the conductive bonding layer 29, the plurality of pillars 24, and the plurality of internal pillars 25 are respectively deposited by electroplating using the seed layer and the plurality of wiring layers 22 as the conductive path. Then, the mask layer used for the lithography patterning is removed. Finally, a wet etching using a mixture of sulfuric acid (H₂SO₄) and hydrogen peroxide (H₂O₂) is performed to remove the portions of the seed layer exposed externally from the plurality of wiring layers 22. As a result, the conductive bonding layer 29, the plurality of pillars 24, and the plurality of internal pillars 25 are formed.

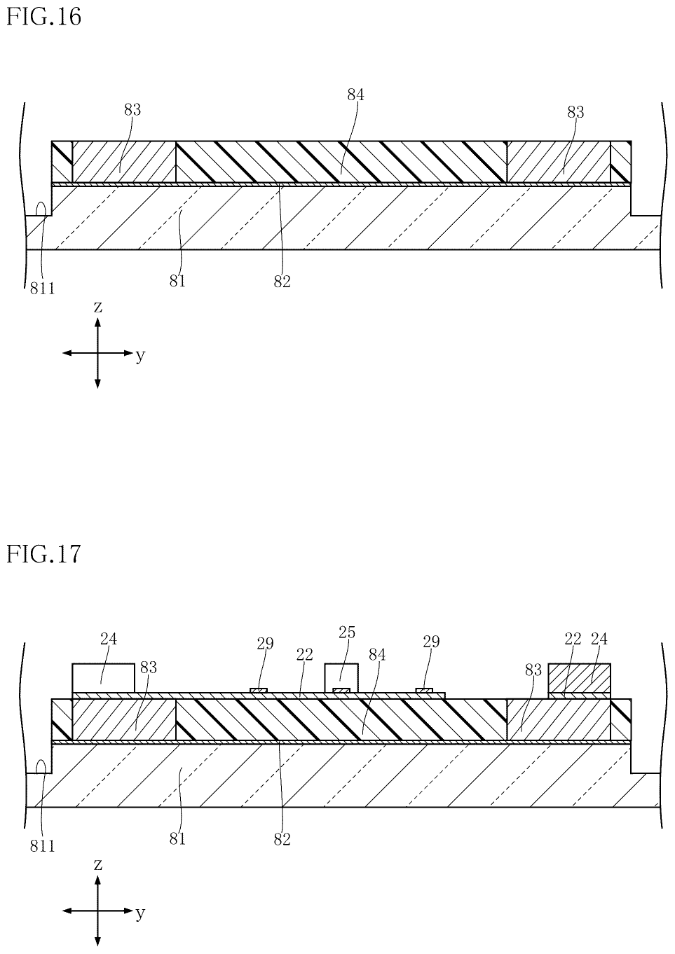

Next, as shown in FIG. 18, the plurality of electrodes 311 of each of the two semiconductor elements 31 are conductively bonded to the plurality of wiring layers 22. The conductive bonding is performed by flip-chip bonding. The conductive bonding of each of the two semiconductor elements 31 is performed by temporarily attaching each of the plurality of electrodes 311 to the conductive bonding layer 29, followed by reflow to melt and solidify the conductive bonding layer 29.

Next, as shown in FIG. 19, a second resin layer 85 is formed to cover the plurality of wiring layers 22, the two semiconductor elements 31, the plurality of pillars 24, and the plurality of internal pillars 25. A portion of the second resin layer 85 forms the first sealing resin 41 which the semiconductor device A10 has. The first sealing resin 41 is made of a material containing black epoxy resin. The second resin layer 85 is formed by transfer mold forming. In this process, the whole of each of the plurality of pillars 24 and the whole of each of the plurality of internal pillars 25 are covered by the second resin layer 85. The mold used to form the second resin layer 85 contacts the surface of the support member 81 that defines the peripheral groove 811.

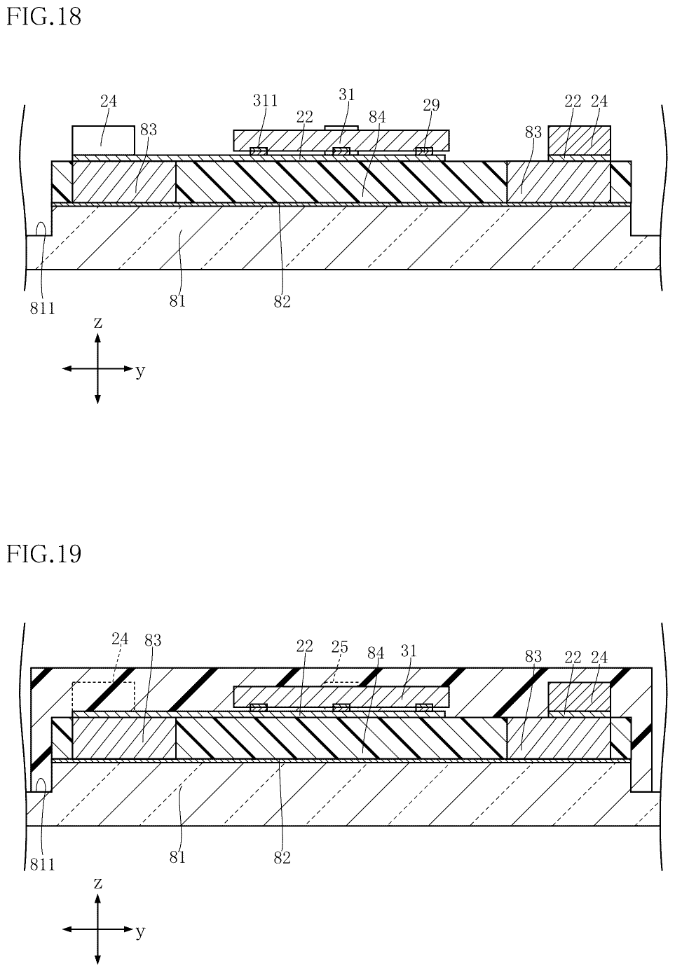

Next, as shown in FIG. 20, a portion of each of the plurality of pillars 24, a portion of each of the plurality of internal pillars 25, and a portion of the second resin layer 85 are removed by grinding. The portions to be removed are those located on a side opposite to the side facing the intermediate layer 82 in the first direction z. As a result, each of the plurality of pillars 24 and each of the plurality of internal pillars 25 are exposed from the surface of the second resin layer 85 facing the first direction z. In this process, a portion of the semiconductor substrate 312 of each of the two semiconductor elements 31 shown in FIG. 9 are also removed by grinding. As a result, the upper surface 31A of each of the two semiconductor elements 31 appear on the surface of the second resin layer 85 facing the first direction z.

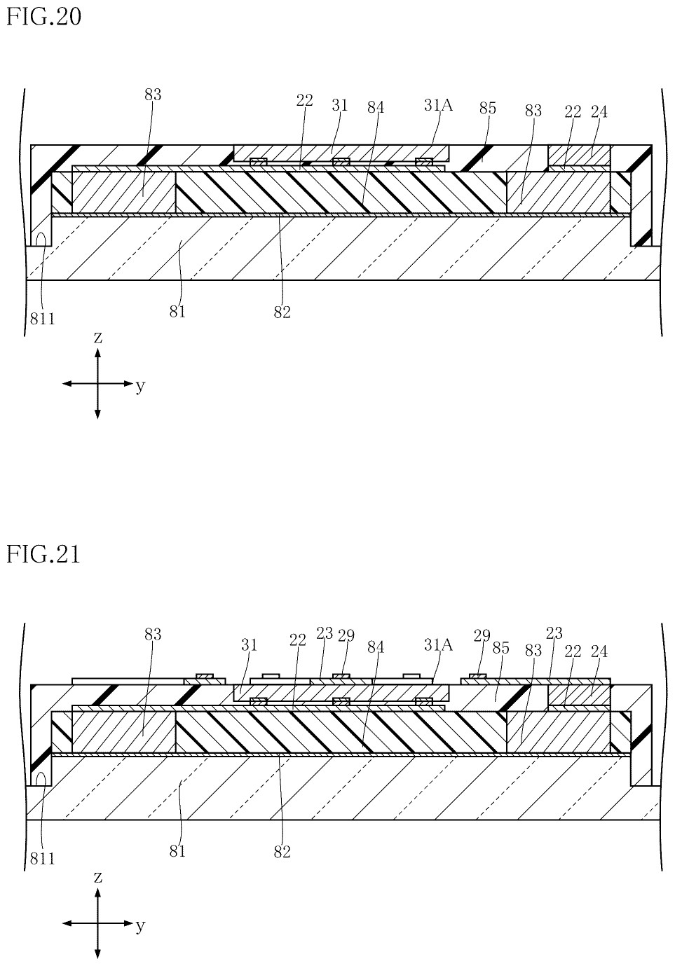

Next, as shown in FIG. 21, the plurality of pillars 24, the plurality of internal pillars 25, and the plurality of metal layers 23 in contact with the second resin layer 85 are formed. Additionally, the conductive bonding layer 29 is laminated on one of the plurality of metal layers 23. The method for forming the plurality of metal layers 23 and the conductive bonding layer 29 is the same as the method for forming the plurality of wiring layers 22 and the conductive bonding layer 29 shown in FIG. 17. In this configuration, one of the plurality of metal layers 23 is arranged to contact the upper surface 31A of at least one of the two semiconductor elements 31.

Next, as shown in FIG. 22, the plurality of electrodes 321 of electronic elements 32 are conductively bonded to the plurality of metal layers 23. The conductive bonding is performed by flip-chip bonding. The conductive bonding of the electronic elements 32 is performed by temporarily attaching each of the plurality of electrodes 321 to the conductive bonding layer 29, followed by reflow to melt and solidify the conductive bonding layer 29.

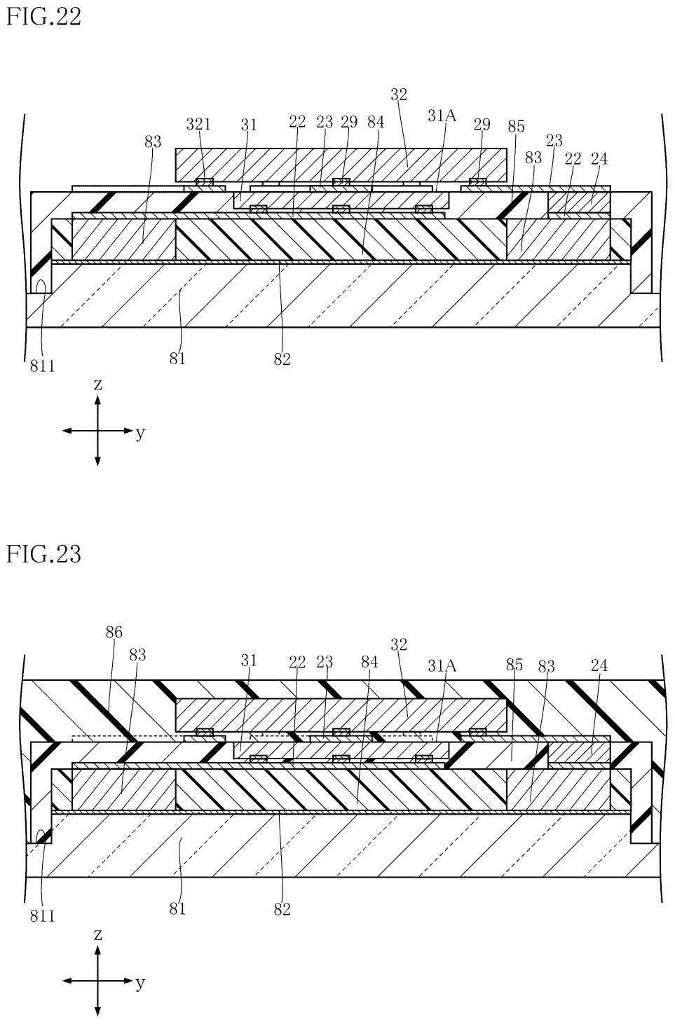

Next, as shown in FIG. 23, a third resin layer 86 is formed to cover the plurality of metal layers 23 and the electronic elements 32. A portion of the third resin layer 86 becomes the second sealing resin 42 which the semiconductor device A10 has. The second sealing resin 42 is made of a material containing black epoxy resin. The third resin layer 86 is formed by transfer mold forming. The mold used to form the third resin layer 86 contacts the surface of the support member 81 that defines the peripheral groove 811.

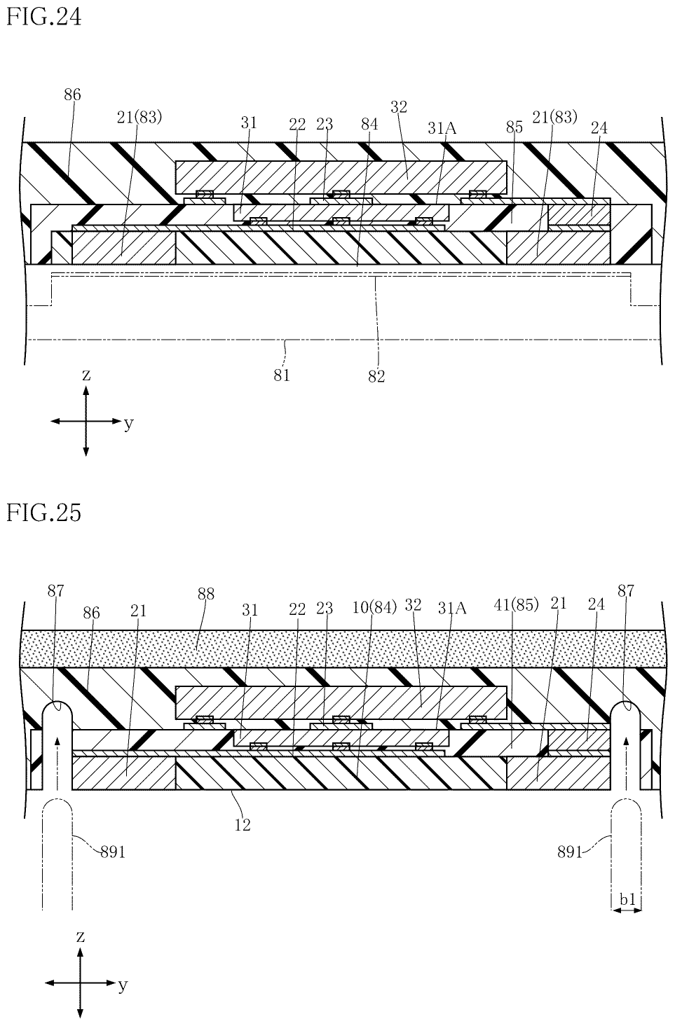

Next, as shown in FIG. 24, the support member 81 and the intermediate layer 82 are removed by grinding. In this process, a portion of each of the plurality of conductive layers 83 and a portion of the first resin layer 84 are removed by grinding. As a result of this process, the plurality of conductive layers 83 become the plurality of terminals 21 which the semiconductor device A10 has.

Next, as shown in FIG. 25, a tape 88 is adhered to the surface of the third resin layer 86. The tape 88 is a dicing tape. Next, using a first blade 891 having a width b1, a portion of each of the first resin layer 84, the second resin layer 85, and the third resin layer 86 is removed to form a plurality of grooves 87 recessed in the first direction z. The plurality of grooves 87 are formed in a grid pattern along the second direction x and the third direction y. Through this process, the first resin layer 84 becomes the insulating layer 10 which the semiconductor device A10 has. Additionally, the second resin layer 85 becomes the first scaling resin 41 which the semiconductor device A10 has. The surface of the insulating layer 10 facing the first direction z and being exposed to the outside corresponds to the bottom surface 12 of the insulating layer 10.

Next, as shown in FIG. 26, a plurality of protective layers 60 are formed to individually cover the surface of each of the plurality of terminals 21 exposed to the outside from the insulating layer 10. In forming the plurality of protective layers 60, first, the surface of each of the plurality of terminals 21 exposed to the outside from the insulating layer 10 is smoothed by wet etching. Then, the plurality of protective layers 60 are formed by electroless plating.

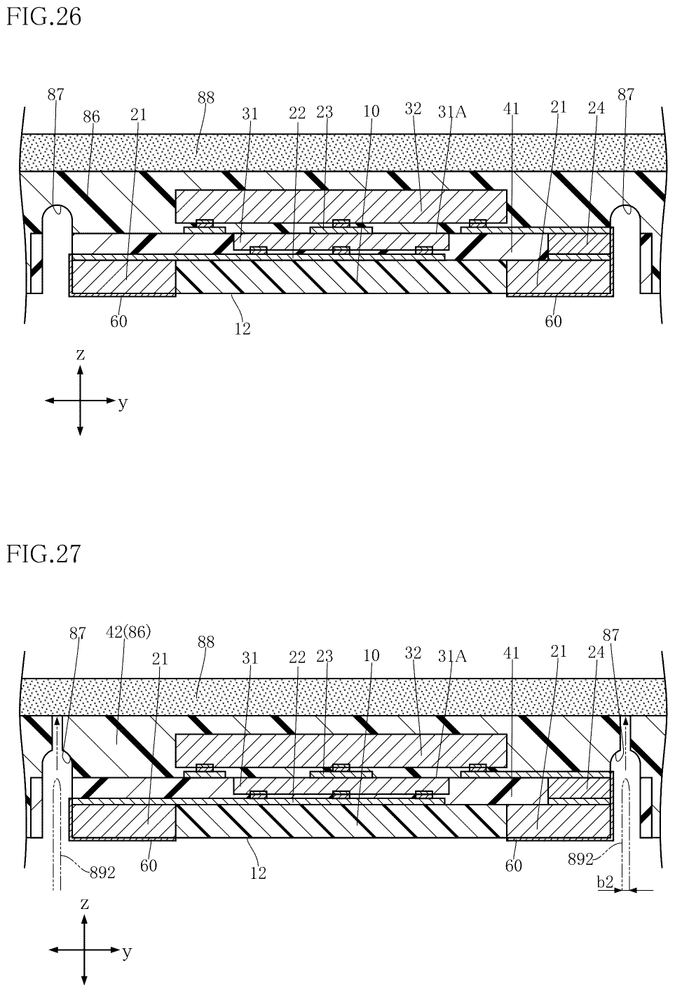

Finally, as shown in FIG. 27, the third resin layer 86 is cut using a second blade 892 having a width b2. The width b2 is smaller than the width b1 of the first blade 891. When cutting the third resin layer 86, the second blade 892 is passed through each of the plurality of grooves 87, and then the second blade 892 is moved in the first direction z until it contacts the tape 88. Through this process, the third resin layer 86 becomes the second sealing resin 42 which the semiconductor device A10 has. By performing the above processes, the semiconductor device A10 is obtained.

Next, the operational effects of the semiconductor device A10 are described.

The semiconductor device A10 includes a first wiring layer 22A, a semiconductor element 31 electrically bonded to the first wiring layer 22A, a second wiring layer 22B spaced apart from the first wiring layer 22A, pillars 24 connected to the second wiring layer 22B and electrically conductive therewith, and a metal layer 23 connected to the pillars 24 and electrically conductive therewith. The metal layer 23 is positioned on a side opposite to the first wiring layer 22A and the second wiring layer 22B with respect to the semiconductor element 31 in the first direction z. The semiconductor element 31 has an upper surface 31A facing the metal layer 23. The metal layer 23 is in contact with the upper surface 31A. By adopting this configuration, the space between the semiconductor element 31 and the metal layer 23 in the first direction z is eliminated, thereby reducing the dimension of the semiconductor device A10 in the first direction z. Furthermore, as viewed in the first direction z, excessive expansion of the metal layer 23 toward the outer side of the semiconductor device A10 is suppressed. Therefore, according to this configuration, even in a case where the metal layer 23 is laminated on the wiring layer 22 with the semiconductor element 31 interposed therebetween, excessive dimensional expansion of the semiconductor device A10 can be suppressed.

The metal layer 23 is electrically conductive with the upper surface 31A of the semiconductor element 31. By adopting this configuration, electrical conductivity from both sides of the semiconductor element 31 in the first direction z can be achieved.

The semiconductor device A10 further includes the first sealing resin 41 covering the semiconductor element 31, the electronic element 32 electrically bonded to the metal layer 23, and the second sealing resin 42 covering the electronic element 32. The first sealing resin 41 has the first surface 411. The upper surface 31A is exposed from the first surface 411. The metal layer 23 is in contact with the first surface 411. The second sealing resin 42 has the second surface 421 and the top surface 422. The surface roughness of each of the first surface 411 and the second surface 421 is greater than the surface roughness of the top surface 422. This configuration is obtained by the process shown in FIG. 20 in the manufacturing process of the semiconductor device A10. That is, this configuration is a result of setting the dimension of the first sealing resin 41 in the first direction z as small as possible by removing a portion of the second resin layer 85 by grinding. Furthermore, the second surface 421 appears because the shape of a surface portion facing the second resin layer 85 of the third resin layer 86, which is formed in the process shown in FIG. 23 in the manufacturing process of the semiconductor device A10, follows the surface of the second resin layer 85. This allows the dimension in the first direction z of the semiconductor device A10 to be further reduced.

The surface roughness of each of the first surface 411 and the second surface 421 is larger than the surface roughness of the top surface 422, causing an anchoring effect (anchor effect) to occur on the second surface 421 with respect to the first surface 411. This improves the adhesion of the second sealing resin 42 with respect to the first sealing resin 41.

The semiconductor element 31 has an end surface 31B facing a direction orthogonal to the first direction z. The end surface 31B is covered by the first sealing resin 41. The surface roughness of the upper surface 31A is greater than the surface roughness of the end surface 31B. This configuration is obtained through the process shown in FIG. 20 in the manufacturing process of the semiconductor device A10. That is, this configuration is the result of removing a portion of the semiconductor substrate 312 of the semiconductor element 31 shown in FIG. 9, along with a portion of the second resin layer 85, by grinding. This allows the dimension of the first sealing resin 41 in the first direction z obtained from the second resin layer 85 to be minimized.

The semiconductor device A10 further includes the insulating layer 10 positioned on the opposite side of the second sealing resin 42 with respect to the first sealing resin 41. The first wiring layer 22A, the second wiring layer 22B, and the first sealing resin 41 each are in contact with the insulating layer 10. By adopting this configuration, the first wiring layer 22A, the second wiring layer 22B, and the first sealing resin 41 can be supported by the insulating layer 10. The insulating layer 10 has a bottom surface 12 facing a side opposite to the side the first surface 411 faces in the first direction z. The surface roughness of the bottom surface 12 is greater than the surface roughness of the top surface 422. This configuration is obtained through the process shown in FIG. 24 in the manufacturing process of the semiconductor device A10. In other words, this configuration is a result of setting the dimension of the insulating layer 10 in the first direction z as small as possible by removing a portion of the first resin layer 84 through grinding. This more effectively suppresses excessive expansion of the dimension of the semiconductor device A10 in the first direction z.

The semiconductor device A10 is accommodated in the insulating layer 10 and further includes terminals 21 that are electrically conductive with either the first wiring layer 22A or the second wiring layer 22B. Terminal 21 is exposed from the bottom surface 12 of insulating layer 10. In this case, the semiconductor device A10 further includes a protective layer 60 that covers a portion of terminal 21 exposed from bottom surface 12. The protective layer 60 is a conductive material containing gold. By adopting this configuration, when the semiconductor device A10 is mounted on a wiring substrate, the wettability of molten solder on the protective layer 60 becomes favorable. This can prevent a reduction in the bonding area of the protective layer 60 with respect to the solder.

The insulating layer 10 has a first side surface 13 facing a direction orthogonal to the first direction z. The terminal 21 is exposed from the first side surface 13. The protective layer 60 covers a portion of the terminal 21 exposed from the first side surface 13. By adopting this configuration, when mounting the semiconductor device A10 on the wiring board, the molten solder can easily flow upward along the protective layer 60 in the first direction z. This promotes the formation of solder fillet. Therefore, the bonding strength of the semiconductor device A10 with respect to the wiring board can be improved. Furthermore, after mounting the semiconductor device A10 on the wiring board, the solder fillet is exposed externally, enabling the mounting condition of the semiconductor device A10 on the wiring board to be easily visually inspected.

The insulating layer 10 has a mounting surface 11 facing a side opposite to the side the bottom surface 12 faces in the first direction z. The terminal 21 has a connection surface 213 facing the same side as the mounting surface 11 in the first direction z. The connection surface 213 is in contact with either the first wiring layer 22A or the second wiring layer 22B. In the first direction z, the connection surface 213 is positioned between the bottom surface 12 and the mounting surface 11 of the insulating layer 10. This configuration is obtained through the process shown in FIG. 17 in the manufacturing process of the semiconductor device A10. By smoothing the surfaces of the plurality of conductive layers 83 by wet etching, the connection surface 213 becomes exposed. As a result, the metal burrs formed on the surface of each of the plurality of conductive layers 83 exposed from the first resin layer 84 are removed, making the surface of either the first wiring layer 22A or the second wiring layer 22B in contact with the connection surface 213 smoother. This has the effect of suppressing noise generation caused by the surface roughness of either the first wiring layer 22A or the second wiring layer 22B.

### Second Embodiment

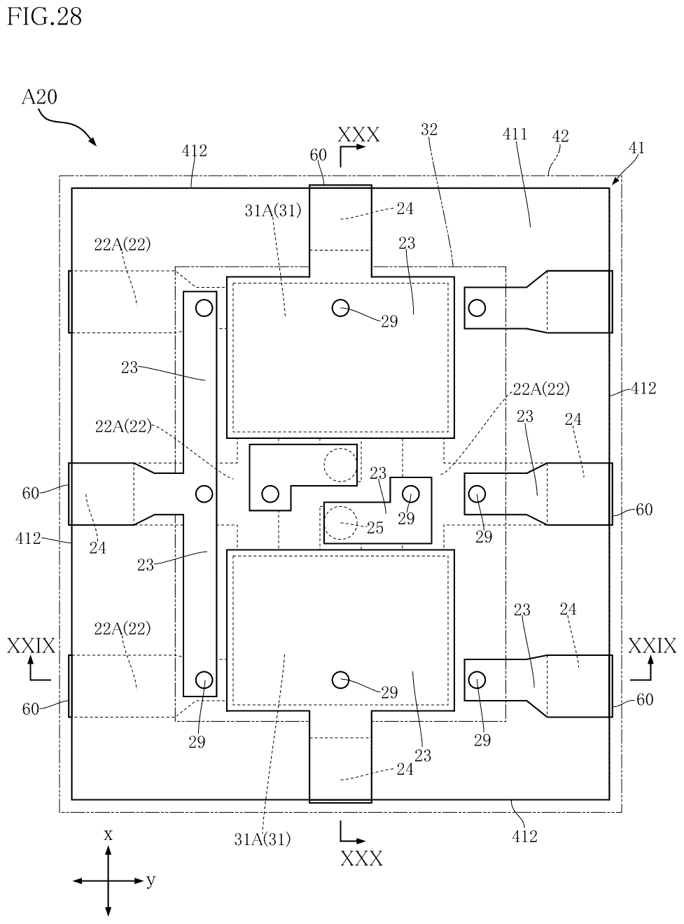

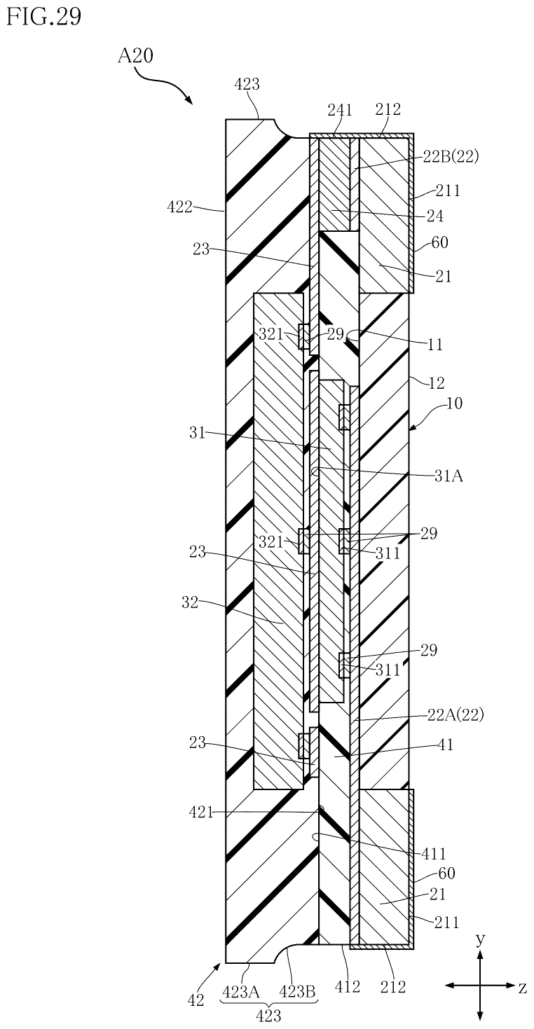

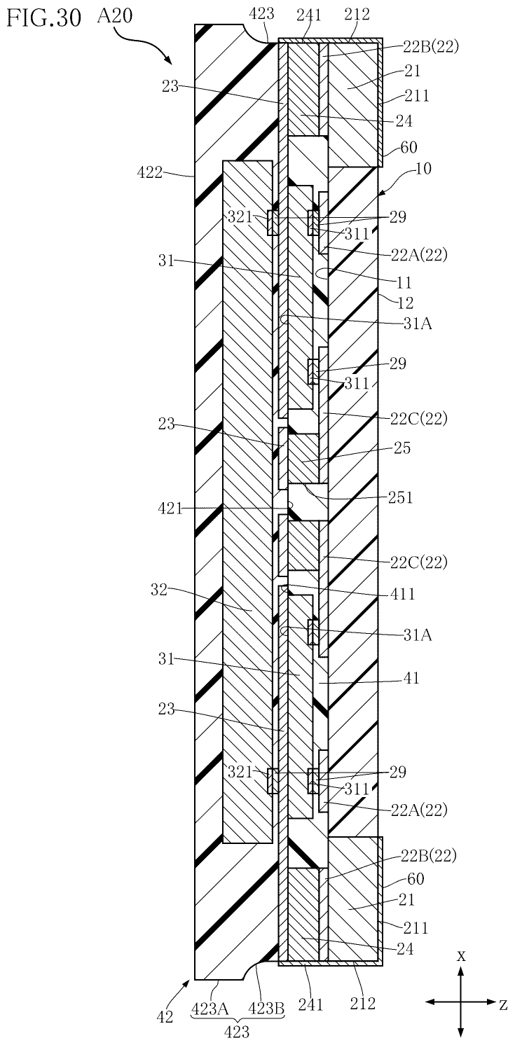

Based on FIGS. 28 to 30, the semiconductor device A20 according to a second embodiment of the present disclosure will be described. In these figures, the same reference numerals are used for the same or similar elements of the semiconductor device A10 as those described above, and redundant descriptions are omitted. Here, FIG. 28 shows the electronic element 32 and the second scaling resin 42 as being transparent for case of understanding. In FIG. 28, each the electronic element 32 and the second sealing resin 42 that are transparent is shown by imaginary lines.

In semiconductor device A20, the configuration of the plurality of metal layers 23 differs from the configuration of semiconductor device A10.

As shown in FIGS. 28 to 30, from among the plurality of metal layers 23, the metal layer 23 in contact with the upper surface 31A of either of the two semiconductor elements 31 covers the whole of the upper surface 31A. As viewed in the first direction z, the metal layer 23 in contact with the upper surface 31A of either of the two semiconductor elements 31 extends outward beyond the upper surface 31A.

Next, the operational effects of the semiconductor device A20 will be described.

The semiconductor device A20 includes the first wiring layer 22A, the semiconductor element 31 conductively bonded to the first wiring layer 22A, the second wiring layer 22B spaced apart from the first wiring layer 22A, the pillars 24 connected to and electrically conductive with the second wiring layer 22B, and the metal layer 23 connected to and electrically conductive with the pillars 24. The metal layer 23 is positioned on the opposite side of the first wiring layer 22A and the second wiring layer 22B with respect to the semiconductor element 31 in the first direction z. The semiconductor element 31 has an upper surface 31A facing the metal layer 23. The metal layer 23 is in contact with the upper surface 31A. Therefore, according to this configuration, even in a case where a metal layer 23 is laminated on the wiring layers 22 with the semiconductor element 31 interposed therebetween, excessive dimensional expansion of the semiconductor device A20 can be suppressed. Furthermore, the semiconductor device A20 has the same configuration as the semiconductor device A10, thereby achieving the same functional effects as the semiconductor device A10.

In semiconductor device A20, the metal layer 23 covers the whole of the upper surface 31A of semiconductor element 31. Furthermore, as viewed in the first direction z, the metal layer 23 extends outward beyond the upper surface 31A. By adopting this configuration, a larger current can be passed through the upper surface 31A. Furthermore, since more heat can be conducted from the semiconductor element 31 to the metal layer 23, it is possible to improve the heat dissipation performance of the semiconductor device A20.

The present disclosure is not limited to the above-described embodiments. The specific configurations of the various parts of the present disclosure may be freely designed and modified. The present disclosure includes the embodiments described in the following clauses.

### Clause 1.

A semiconductor device comprising:
a first wiring layer;
a semiconductor element conductively bonded to the first wiring layer;
a second wiring layer positioned on a same side in a first direction as the first wiring layer with respect to the semiconductor element and spaced apart from the first wiring layer;
a pillar connected and conductively bonded to the second wiring layer;
a metal layer positioned on a side opposite to the first wiring layer and the second wiring layer with respect to the semiconductor element, and connected to and electrically conductive with the pillar,
wherein the semiconductor element has an upper surface facing the metal layer, and
the metal layer is in contact with the upper surface.

### Clause 2.

The semiconductor device according to clause 1, wherein the metal layer is electrically conductive with the upper surface.

### Clause 3.

The semiconductor device according to clause 2, further comprising a first sealing resin covering the semiconductor element,
wherein the first wiring layer, the second wiring layer and the pillar are accommodated in the first sealing resin,
the first sealing resin has a first surface facing a same side the upper surface faces in the first direction,
the upper surface is exposed from the first surface, and
the metal layer is in contact with the first surface.

### Clause 4.

The semiconductor device according to clause 3, further comprising:
an electronic element overlapping the semiconductor element as viewed in the first direction and conductively bonded to the metal layer; and
a second sealing resin covering the electronic element,
wherein the metal layer is accommodated in the second sealing resin,
the second sealing resin has a second surface in contact with the first surface and a top surface facing a side opposite to a side the second surface faces in the first direction, and
a surface roughness of each of the first surface and the second surface is larger than a surface roughness of the top surface.

### Clause 5.

The semiconductor device according to clause 4,
wherein the semiconductor element has an end surface facing a direction orthogonal to the first direction,
the end surface is covered by the first sealing resin, and
a surface roughness of the upper surface is larger than a surface roughness of the end surface.

### Clause 6.

The semiconductor device according to clause 4, wherein the second surface is in contact with the upper surface.

### Clause 7.

The semiconductor device according to clause 4, wherein the metal layer covers a whole of the upper surface.

### Clause 8.

The semiconductor device according to clause 7, wherein the metal layer extends outward beyond the upper surface as viewed in the first direction.

### Clause 9.

The semiconductor device according to any of clauses 4 to 8, further comprising an insulating layer positioned on a side opposite to the second sealing resin with respect to the first sealing resin,
wherein each of the first wiring layer, the second wiring layer and the first sealing resin is in contact with the insulating layer.

### Clause 10.

The semiconductor device according to clause 9, further comprising a terminal connected to and electrically conductive with either the first wiring layer or the second wiring layer,
wherein the terminal is accommodated in the insulating layer,
the insulating layer has a bottom surface facing a side opposite to a side the first surface faces in the first direction, and
the terminal is exposed from the bottom surface.

### Clause 11.

The semiconductor device according to clause 10, wherein a surface roughness of the bottom surface is larger than a surface roughness of the top surface.

### Clause 12.

The semiconductor device according to clause 11,
wherein the insulating layer has a mounting surface facing a side opposite to a side the bottom surface faces in the first direction,
the terminal has a connection surface facing a side same as a side the mounting surface faces in the first direction,
the connection surface is in contact with either the first wiring layer or the second wiring layer, and
the connection surface is positioned between the bottom surface and the mounting surface in the first direction.

### Clause 13.

The semiconductor device according to clause 11,
wherein the insulating layer has a first side surface facing a direction orthogonal to the first direction, and
the terminal is exposed from the first side surface.

### Clause 14.

The semiconductor device according to clause 13, further comprising a protective layer covering a portion of the terminal exposed from each of the bottom surface and the first side surface,
wherein the protective layer is a conductor containing gold.

### Clause 15.

The semiconductor device according to clause 14,
wherein the first sealing resin has a second side surface facing a direction orthogonal to the first direction, and
a surface roughness of the second side surface is smaller than a surface roughness of the first surface, and is larger than a surface roughness of the top surface.

### Clause 16.

The semiconductor device according to clause 15,
wherein the second sealing resin has a third side surface connected to the second surface and the top surface, and
the third side surface has a portion located outward from the second side surface as viewed in the first direction.

### REFERENCE NUMERALS

A10, A20: Semiconductor device 10: Insulating layer
11: Mounting surface 12: Bottom surface
13: First side surface 21: Terminal
211: Implementing surface 212: Side surface
213: Connection surface 22: Wiring layer
22A-22C: First wiring layer-Third wiring layer 221: First end surface
23: Metal layer 231: Second end surface
24: Pillar 241 First circumferential surface
25: Internal pillar 251 Second circumferential surface
29: Conductive bonding layer 31: Semiconductor element
31A: Upper surface 31B: End surface
311: Electrode 312: Semiconductor substrate
313: Semiconductor layer 32: Electronic element
321: Electrode 41: First sealing resin
411: First surface 412: Second side surface
42: Second sealing resin 421: Second surface
422: Top surface 423: Third side surface
423A: First region 423B: Second region
60: Protective layer
81: Support member 82: Intermediate layer
83: Conductive layer 84: First resin layer
85: Second resin layer 86: Third resin layer
87: Groove 88: Tape
891: First blade 892: Second blade
z: First direction x: Second direction
y: Third direction

1. A semiconductor device comprising:
a first wiring layer;
a semiconductor element conductively bonded to the first wiring layer;
a second wiring layer positioned on a same side in a first direction as the first wiring layer with respect to the semiconductor element and spaced apart from the first wiring layer;
a pillar connected and conductively bonded to the second wiring layer;
a metal layer positioned on a side opposite to the first wiring layer and the second wiring layer with respect to the semiconductor element, and connected to and electrically conductive with the pillar,
wherein the semiconductor element has an upper surface facing the metal layer, and
the metal layer is in contact with the upper surface.

2. The semiconductor device according to claim 1, wherein the metal layer is electrically conductive with the upper surface.

3. The semiconductor device according to claim 2, further comprising a first sealing resin covering the semiconductor element,
wherein the first wiring layer, the second wiring layer and the pillar are accommodated in the first sealing resin,
the first sealing resin has a first surface facing a same side the upper surface faces in the first direction,
the upper surface is exposed from the first surface, and
the metal layer is in contact with the first surface.

4. The semiconductor device according to claim 3, further comprising:
an electronic element overlapping the semiconductor element as viewed in the first direction and conductively bonded to the metal layer; and
a second sealing resin covering the electronic element,
wherein the metal layer is accommodated in the second sealing resin,
the second sealing resin has a second surface in contact with the first surface and a top surface facing a side opposite to a side the second surface faces in the first direction, and
a surface roughness of each of the first surface and the second surface is larger than a surface roughness of the top surface.

5. The semiconductor device according to claim 4,
wherein the semiconductor element has an end surface facing a direction orthogonal to the first direction,
the end surface is covered by the first sealing resin, and
a surface roughness of the upper surface is larger than a surface roughness of the end surface.

6. The semiconductor device according to claim 4, wherein the second surface is in contact with the upper surface.

7. The semiconductor device according to claim 4, wherein the metal layer covers a whole of the upper surface.

8. The semiconductor device according to claim 7, wherein the metal layer extends outward beyond the upper surface as viewed in the first direction.

9. The semiconductor device according to claim 4, further comprising an insulating layer positioned on a side opposite to the second sealing resin with respect to the first sealing resin,
wherein each of the first wiring layer, the second wiring layer and the first sealing resin is in contact with the insulating layer.

10. The semiconductor device according to claim 9, further comprising a terminal connected to and electrically conductive with either the first wiring layer or the second wiring layer,
wherein the terminal is accommodated in the insulating layer,
the insulating layer has a bottom surface facing a side opposite to a side the first surface faces in the first direction, and
the terminal is exposed from the bottom surface.

11. The semiconductor device according to claim 10,
wherein a surface roughness of the bottom surface is larger than a surface roughness of the top surface.

12. The semiconductor device according to claim 11,
wherein the insulating layer has a mounting surface facing a side opposite to a side the bottom surface faces in the first direction,
the terminal has a connection surface facing a side same as a side the mounting surface faces in the first direction,
the connection surface is in contact with either the first wiring layer or the second wiring layer, and
the connection surface is positioned between the bottom surface and the mounting surface in the first direction.

13. The semiconductor device according to claim 11,
wherein the insulating layer has a first side surface facing a direction orthogonal to the first direction, and
the terminal is exposed from the first side surface.

14. The semiconductor device according to claim 13, further comprising a protective layer covering a portion of the terminal exposed from each of the bottom surface and the first side surface,
wherein the protective layer is a conductor containing gold.

15. The semiconductor device according to claim 14,
wherein the first sealing resin has a second side surface facing a direction orthogonal to the first direction, and
a surface roughness of the second side surface is smaller than a surface roughness of the first surface, and is larger than a surface roughness of the top surface.

16. The semiconductor device according to claim 15,
wherein the second sealing resin has a third side surface connected to the second surface and the top surface, and
the third side surface has a portion located outward from the second side surface as viewed in the first direction.
